(19) United States
(12) Patent Application Publication
(10) Pub. No.: US 2025/0220899 A1
(43) Pub. Date: Jul. 3, 2025

(54) SEMICONDUCTOR DEVICES AND ELECTRONIC SYSTEMS INCLUDING THE SAME

(71) Applicant: Samsung Electronics Co., Ltd., Suwon-si (KR)

(72) Inventors: Gilsung Lee, Suwon-si (KR); Sunil Shim, Suwon-si (KR); Junyoul Yang, Suwon-si (KR); Seungjun Lee, Suwon-si (KR); Jeayeon Lee, Suwon-si (KR); Juyul Lee, Suwon-si (KR); Yongmoon Jang, Suwon-si (KR); Wonseok Cho, Suwon-si (KR)

(21) Appl. No.: 18/966,486

(22) Filed: Dec. 3, 2024

(30) Foreign Application Priority Data
Dec. 29, 2023 (KR) 10-2023-0197641

(51) Int. Cl. H10B 41/35; H10B 41/41; H10B 43/35; H10B 43/40

(52) U.S. Cl. CPC H10B 41/35; H10B 41/41; H10B 43/35; H10B 43/40

(57) ABSTRACT

A semiconductor device may include a plurality of gate lines including a first gate line and a second gate line arranged over the first gate line, a plurality of insulating layers respectively arranged between the plurality of gate lines, a plurality of channel structures penetrating the plurality of gate lines in a vertical direction that is perpendicular to an upper surface of the substrate, and a separation pattern overlapping at least a portion of the plurality of channel structures in the vertical direction. The separation pattern may penetrate at least a portion of the second gate line and at least a portion of a first channel structure of the plurality of channel structures. The first channel structure may overlap the separation pattern in the vertical direction. The second gate line may be filled completely with a conductive material.

### CROSS-REFERENCE TO RELATED APPLICATION

This application is based on and claims priority under 35 U.S.C. § 119 to Korean Patent Application No. 10-2023-0197641, filed on Dec. 29, 2023, in the Korean Intellectual Property Office, the disclosure of which is incorporated by reference herein in its entirety.

### BACKGROUND

The inventive concepts relate to semiconductor devices and to electronic systems including semiconductor devices. More particularly, the inventive concepts relate to semiconductor devices including nonvolatile vertical memory devices and to electronic system including such semiconductor device.

Semiconductor devices that are capable of storing high-capacity data have been increasingly important in electronic systems requiring data storage, and accordingly, schemes capable of increasing the data storage capacity of semiconductor devices have been researched. For example, one method that has been proposed for increasing the data storage capacity of is including a vertical memory device having three-dimensionally arranged memory cells instead of two-dimensionally arranged memory cells.

### SUMMARY

The inventive concepts provide semiconductor devices with improved electrical characteristics and operational reliability, methods of forming the semiconductor devices, and electronic systems including the semiconductor devices.

According to some aspects of the inventive concepts, there is provided a semiconductor device including a plurality of gate lines including a first gate line arranged over a substrate and a second gate line arranged over the first gate line, a plurality of insulating layers respectively arranged between the plurality of gate lines, a plurality of channel structures that penetrate the plurality of gate lines in a vertical direction that is perpendicular to an upper surface of the substrate, and a separation pattern that overlaps at least a portion of the plurality of channel structures in the vertical direction. The separation pattern may penetrate at least a portion of the second gate line and at least a portion of a first channel structure of the plurality of channel structures, the first channel structure overlapping the separation pattern in the vertical direction among the plurality of channel structures. The second gate line may be filled completely with a conductive material.

According to some aspects of the inventive concepts, there is provided a semiconductor device including a peripheral circuit structure including a substrate, a peripheral circuit arranged over the substrate, and a peripheral circuit line structure connected to the peripheral circuit, a common source plate arranged over the peripheral circuit structure, a plurality of gate lines including a first gate line arranged over the common source plate and a second gate line arranged over the first gate line, a plurality of insulating layers respectively arranged between the plurality of gate lines, a plurality of channel structures that penetrate the plurality of gate lines in a vertical direction perpendicular to an upper surface of the substrate, a first separation pattern that is horizontally spaced apart from the plurality of channel structures and that penetrates the plurality of gate lines in the vertical direction, and a second separation pattern that is horizontally spaced apart from the first separation pattern and that overlaps at least a portion of the plurality of channel structures in the vertical direction. The second separation pattern may penetrate at least a portion of the second gate line and at least a portion of a first channel structure of the plurality of channel structures, the first channel structure overlapping the second separation pattern in the vertical direction. The second gate line may be filled completely with a conductive material.

According to some aspects of the inventive concepts, there is provided an electronic system including a main board, a semiconductor device over the main board, and a controller electrically connected to the semiconductor device. The semiconductor device includes a plurality of gate lines including a first gate line that is arranged over a substrate and a second gate line that is arranged over the first gate line, a plurality of insulating layers respectively arranged between the plurality of gate lines, a plurality of channel structures that penetrate the plurality of gate lines in a vertical direction that is perpendicular to an upper surface of the substrate, and a separation pattern that overlaps at least a portion of the plurality of channel structures in the vertical direction. The separation pattern may penetrate at least a portion of the second gate line and at least a portion of a first channel structure of the plurality of channel structures, the first channel structure overlapping the separation pattern in the vertical direction. The second gate line may be filled completely with a conductive material.

### BRIEF DESCRIPTION OF THE DRAWINGS

Embodiments will be more clearly understood from the following detailed description taken in conjunction with the accompanying drawings in which:

FIG. 1 is a block diagram illustrating a semiconductor device according to some embodiments;

FIG. 2 is an equivalent circuit diagram of a memory cell array of a semiconductor device according to some embodiments;

FIG. 3 is a perspective view schematically illustrating a semiconductor device according to some embodiments;

FIG. 4 is a plan layout diagram schematically illustrating a semiconductor device according to some embodiments;

FIG. 5 is a cross-sectional view of the semiconductor device taken along line A-A′ of FIG. 4;

FIG. 6 is a cross-sectional view of the semiconductor device taken along line B-B′ of FIG. 4;

FIG. 7 is an enlarged cross-sectional view of region EX1 of FIG. 5;

FIG. 8 is an enlarged cross-sectional view of region EX2 of FIG. 6;

FIG. 9 is an enlarged cross-sectional view of a region corresponding to region EX2 of FIG. 6;

FIGS. 10A, 10B, 11, 12A, 12B, 13A, 13B, 13C, 14A, 14B, 15, 16A, 16B, 17A, and 17B are cross-sectional views for describing a semiconductor device manufacturing method according to some embodiments;

FIG. 18 is a diagram schematically illustrating an electronic system including a semiconductor device according to some embodiments;

FIG. 19 is a perspective view schematically illustrating an electronic system including a semiconductor device according to some embodiments; and

FIG. 20 is a cross-sectional view schematically illustrating semiconductor packages according to some embodiments.

### DETAILED DESCRIPTION OF THE EMBODIMENTS

Hereinafter, some examples of embodiments of the inventive concepts will be described in detail and with reference to the accompanying drawings. Herein, like reference numerals will denote like elements, and redundant descriptions thereof may be omitted for conciseness.

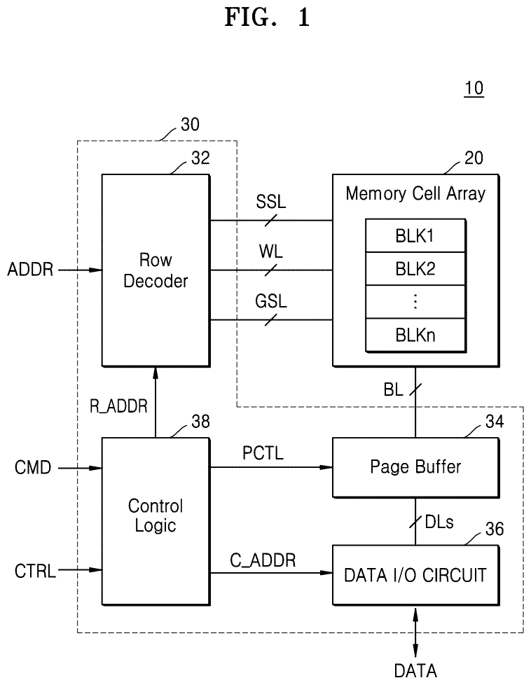

FIG. 1 is a block diagram illustrating a semiconductor device 10 according to some embodiments.

Referring to FIG. 1, the semiconductor device 10 may include a memory cell array 20 and a peripheral circuit 30. The memory cell array 20 may include a plurality of memory cell blocks BLK1, BLK2, . . . , BLKn. Each of the plurality of memory cell blocks BLK1, BLK2, . . . , BLKn may include a plurality of memory cells. The memory cell blocks BLK1, BLK2, . . . , BLKn may be connected to the peripheral circuit 30 through a plurality of bit lines BL, a plurality of word lines WL, a plurality of string selection lines SSL, and a plurality of ground selection lines GSL.

The peripheral circuit 30 may include a row decoder 32, a page buffer 34, a data input/output circuit 36, and a control logic 38. Although not illustrated in FIG. 1, the peripheral circuit 30 may further include an input/output interface, a column logic, a voltage generator, a predecoder, a temperature sensor, a command decoder, an address decoder, an amplifier circuit, and/or the like.

The memory cell array 20 may be connected to the page buffer 34 through the plurality of bit lines BL and may be connected to the row decoder 32 through the plurality of word lines WL, the plurality of string selection lines SSL, and the plurality of ground selection lines GSL. In the memory cell array 20, each of the plurality of memory cells included in the plurality of memory cell blocks BLK1, BLK2, . . . , BLKn may be a flash memory cell. The memory cell array 20 may include a three-dimensional memory cell array. The three-dimensional memory cell array may include a plurality of NAND strings, and each NAND string may include a plurality of memory cells connected to a plurality of word lines WL vertically stacked over a substrate.

The peripheral circuit 30 may receive an address ADDR, a command CMD, and a control signal CTRL from a device (not shown) that is external to the semiconductor device 10 and may transmit/receive data DATA to/from the device (or another device) that is external to the semiconductor device 10.

The row decoder 32 may select at least one of the plurality of memory cell blocks BLK1, BLK2, . . . , BLKn in response to the address ADDR from the outside and select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array 20 through the plurality of bit lines BL. The page buffer 34 may operate as a write driver in a program operation to apply a voltage according to data DATA to be stored in the memory cell array 20 to the bit line BL and may operate as a sense amplifier in a read operation to sense data DATA stored in the memory cell array 20. The page buffer 34 may operate according to a control signal PCTL received from the control logic 38.

The data input/output circuit 36 may be connected to the page buffer 34 through a plurailty of data lines DLs. In a program operation, the data input/output circuit 36 may receive data DATA from a memory controller (not illustrated) and provide program data DATA to the page buffer 34 based on a column address C_ADDR received from the control logic 38. In a read operation, the data input/output circuit 36 may provide the read data DATA stored in the page buffer 34 to the memory controller based on the column address C_ADDR received from the control logic 38.

The data input/output circuit 36 may transmit an input address or command to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide a column address C_ADDR to the data input/output circuit 36. The control logic 38 may generate various internal control signals used in the semiconductor device 10 in response to the control signal CTRL. For example, the control logic 38 may adjust a voltage level provided to the plurality of word lines WL and the plurality of bit lines BL in a memory operation such as a program operation or an erase operation.

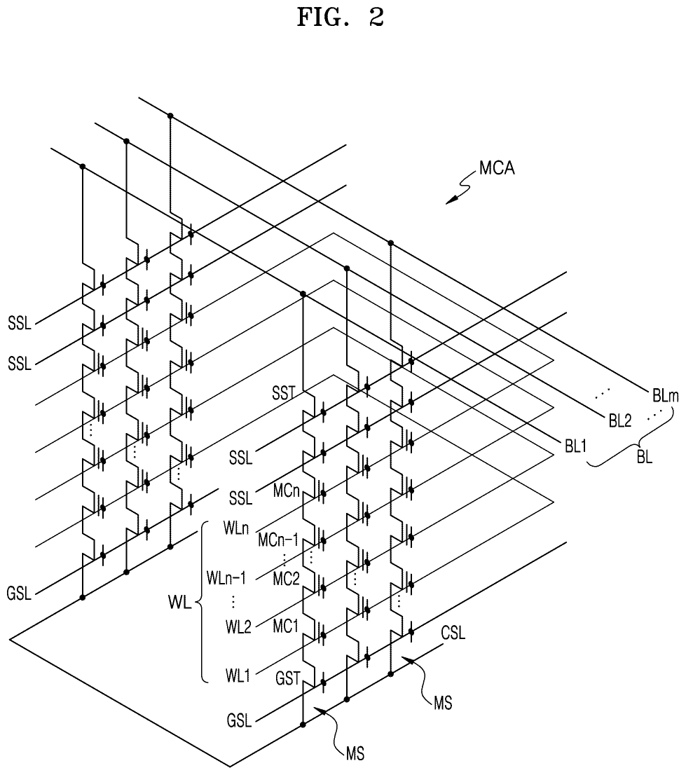

FIG. 2 is an equivalent circuit diagram of a memory cell array MCA of a semiconductor device according to some embodiments. The memory cell array MCA illustrated in FIG. 2 may correspond to the memory cell array 20 described with reference to FIG. 1.

Referring to FIG. 2, the memory cell array MCA may include a plurality of memory cell strings MS. The memory cell array MCA may include a plurality of bit lines BL (BL1, BL2, . . . , BLm), a plurality of word lines WL (WL1, WL2, . . . , WLn−1, WLn), at least one string selection line SSL, at least one ground selection line GSL, and a common source line CSL. The plurality of memory cell strings MS may be formed between the plurality of bit lines BL (BL1, BL2, . . . , BLm) and the common source line CSL. Although FIG. 2 illustrates a case where each of the plurality of memory cell strings MS includes two string selection lines SSL, the inventive concepts of the present disclosure are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn−1, MCn. A drain area of the string selection transistor SST may be connected to the bit lines BL (BL1, BL2, . . . , BLm), and a source area of the ground selection transistor GST may be connected to the common source line CSL. The common source line CSL may be an area where the source areas of a plurality of ground selection transistors GST are connected in common.

The string selection transistor SST may be connected to the string selection line SSL, and the ground selection transistor GST may be connected to the ground selection line GSL. The plurality of memory cell transistors MC1, MC2, . . . , MCn−1, and MCn may be respectively connected to the plurality of word lines WL (WL1, WL2, . . . , WLn−1, WLn).

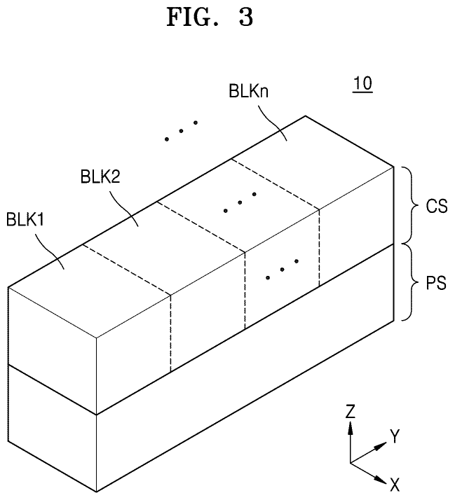

FIG. 3 is a perspective view schematically illustrating a semiconductor device 10 according to some embodiments.

The semiconductor device 10 may include a cell array structure CS and a peripheral circuit structure PS that overlap each other in the vertical direction (Z direction). The cell array structure CS may include the memory cell array 20 described with reference to FIG. 1 and the memory cell array MCA described with reference to FIG. 2, and the peripheral circuit structure PS may include the peripheral circuit 30 described with reference to FIG. 1.

The cell array structure CS may include a plurality of memory cell blocks BLK1, BLK2, . . . , BLKn. Each of the plurality of memory cell blocks BLK1, BLK2, . . . , BLKn may include three-dimensionally arranged memory cells.

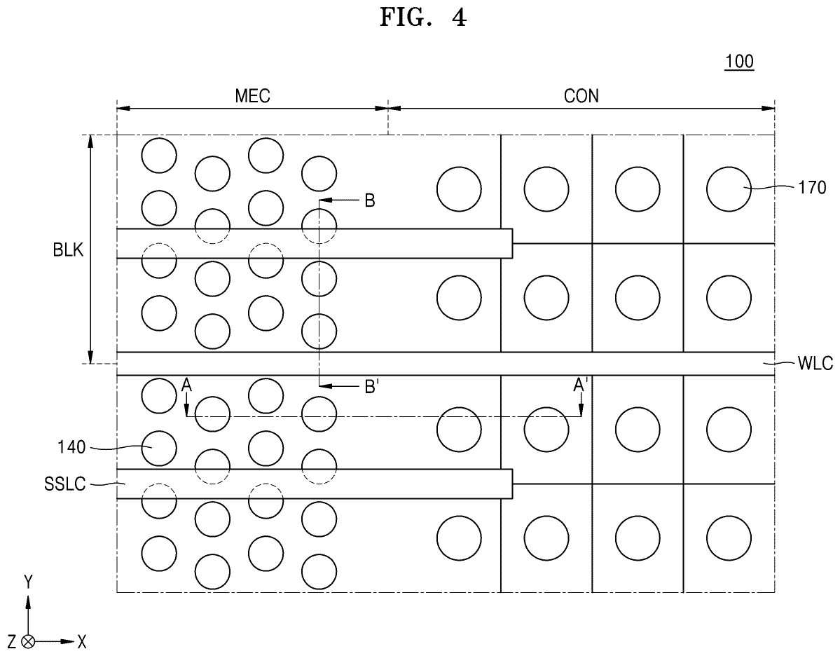

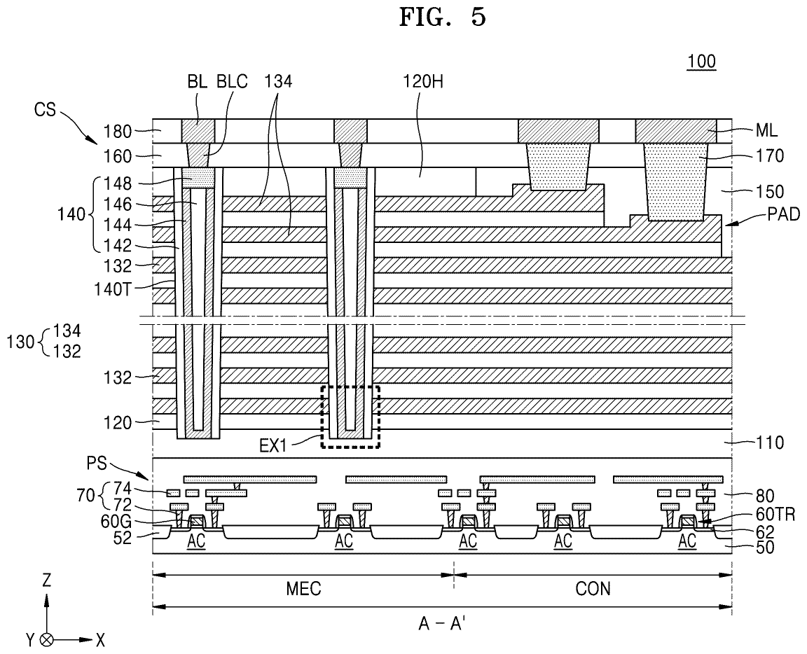

FIG. 4 is a plan layout diagram schematically illustrating a semiconductor device 100 according to some embodiments. FIG. 5 is a cross-sectional view taken along line A-A′ of FIG. 4.

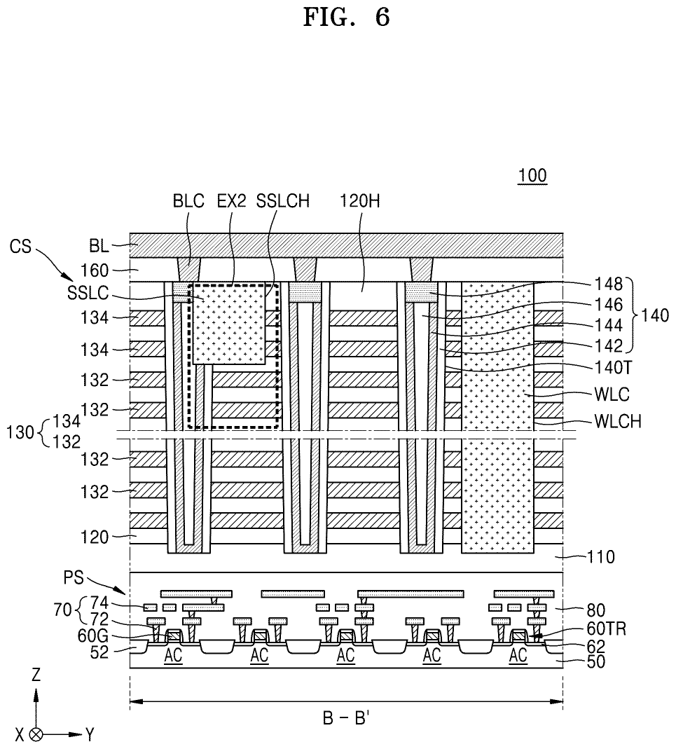

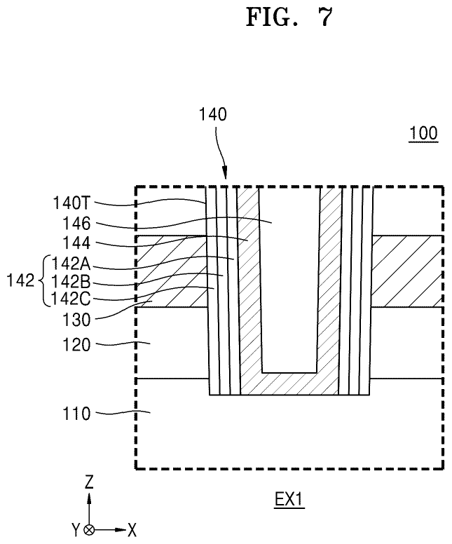

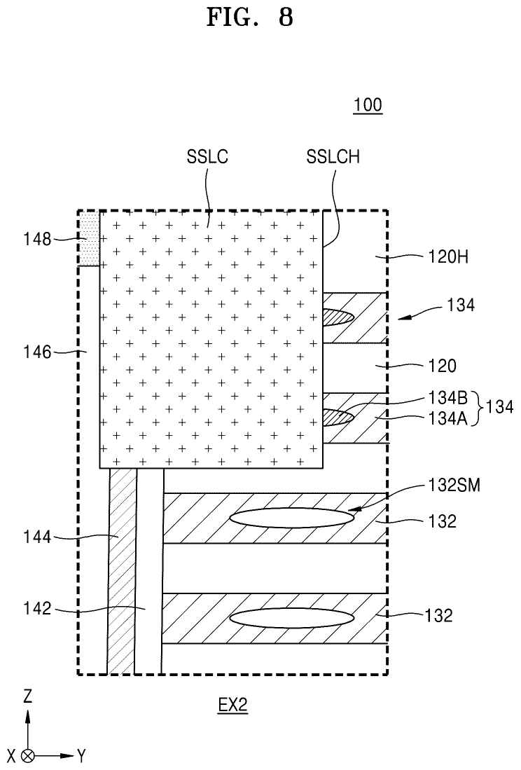

FIG. 6 is a cross-sectional view taken along line B-B′ of FIG. 4. FIG. 7 is an enlarged cross-sectional view of region EX1 of FIG. 5. FIG. 8 is an enlarged cross-sectional view of region EX2 of FIG. 6.

Referring to FIGS. 4 to 8, the semiconductor device 100 may include a peripheral circuit structure PS and a cell array structure CS that is arranged over the peripheral circuit structure PS and that overlaps the peripheral circuit structure PS in the vertical direction (Z direction).

The peripheral circuit structure PS may include a substrate 50, peripheral circuit transistors 60TR arranged over the substrate 50, and a peripheral circuit line structure 70 for connecting the peripheral circuit transistors 60TR to each other or connecting the peripheral circuit transistors 60TR to the components in the cell array structure CS.

The substrate 50 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium. The substrate 50 may be provided as a bulk wafer or as an epitaxial layer. In some embodiments, the substrate 50 may include a silicon-on-insulator (SOI) substrate or a germanium-on-insulator (GeOI) substrate.

A plurality of active areas AC may be defined in the substrate 50 by a device isolation layer 52. The device isolation layer 52 may be arranged in a device isolation trench (not illustrated) formed on the substrate 50. In some embodiments, the device isolation layer 52 may include a silicon oxide, a silicon nitride, a silicon oxynitride, or a combination of two or more thereof.

A peripheral circuit transistor 60TR may be formed over the plurality of active areas AC. The peripheral circuit transistor 60TR may include a peripheral circuit gate 60G and a source/drain area 62 arranged in a portion of the substrate 50 on both sides of the peripheral circuit gate 60G. The peripheral circuit transistor 60TR may constitute a plurality of peripheral circuits included in the peripheral circuit structure PS. The plurality of peripheral circuits including the peripheral circuit transistor 60TR may include various circuits included in the peripheral circuit 30 described with reference to FIG. 1. For example, the plurality of peripheral circuits may include the row decoder 32, the page buffer 34, the data input/output circuit 36, and the control logic 38 illustrated in FIG. 1.

The peripheral circuit line structure 70 may include a plurality of peripheral circuit contacts 72 and a plurality of peripheral circuit line layers 74. The plurality of peripheral circuit line layers 74 may have a multilayer structure including a plurality of metal layers arranged at different vertical levels. At least some of the plurality of peripheral circuit line layers 74 may be configured to be electrically connected to the peripheral circuit transistor 60TR. The plurality of peripheral circuit contacts 72 may be configured to connect the peripheral circuit transistor 60TR and some of the plurality of peripheral circuit line layers 74 to each other.

An interlayer insulating layer 80 may be arranged over the substrate 50 and may cover the peripheral circuit transistor 60TR and the peripheral circuit line structure 70. The interlayer insulating layer 80 may include, for example, a silicon oxide layer, a silicon nitride layer, a SiON layer, a SiOCN layer, or any combination thereof.

The cell array structure CS may be arranged over the interlayer insulating layer 80. The cell array structure CS may include a memory cell area MEC and a connection area CON arranged on both sides of the memory cell area MEC in a first horizontal direction (X direction). A common source plate 110, a plurality of insulating layers 120, a plurality of gate lines 130, and a channel structure 140 may be arranged in the memory cell area MEC of the cell array structure CS, and a common source plate 110, a plurality of insulating layers 120, a plurality of gate lines 130, a plurality of gate pad portions PAD, and a first contact plug 170 may be arranged in the connection area CON of the cell array structure CS.

The common source plate 110 may function as the common source line CSL (see FIG. 2) and may be configured to supply a current to vertical memory cells formed in the cell array structure CS. In some embodiments, the common source plate 110 may include silicon (Si), germanium (Ge), silicon germanium (SiGe), gallium arsenide (GaAs), indium gallium arsenide (InGaAs), aluminum gallium arsenide (AlGaAs), or any mixture or combination thereof. In some embodiments, the common source plate 110 may include a semiconductor doped with a dopant. For example, the common source plate 110 may include polysilicon doped with an n-type dopant. In embodiments, the common source plate 110 may have a crystalline structure including at least one of a monocrystalline structure, an amorphous structure, and a polycrystalline structure.

A plurality of insulating layers 120 and a plurality of gate lines 130 may be alternately stacked over the common source plate 110 in the vertical direction (Z direction). Ones of the plurality of insulating layers 120 may be arranged between the common source plate 110 and the lowermost gate line 130 and between adjacent gate lines 130 of the plurality of gate lines 130, and an uppermost insulating layer 120H among the plurality of insulating layers 120 may cover the uppermost gate line 130. Each of the plurality of insulating layers 120 may include, for example, a silicon oxide.

The plurality of gate lines 130 may include a plurality of first gate lines 132 and a plurality of second gate lines 134. In this case, the first gate line 132 may refer to a gate line that is not at least partially penetrated by a second separation pattern SSLC among the plurality of gate lines 130, and the second gate line 134 may refer to a gate line that is at least partially penetrated by the second separation pattern SSLC among the plurality of gate lines 130. For example, as illustrated in FIGS. 4 to 8, when the second separation pattern SSLC penetrates at least a portion of each of two uppermost gate lines among the plurality of gate lines 130, the two uppermost gate lines may be referred to as the second gate lines 134 and the other gate lines other than the two uppermost gate lines may be referred to as the first gate lines 132.

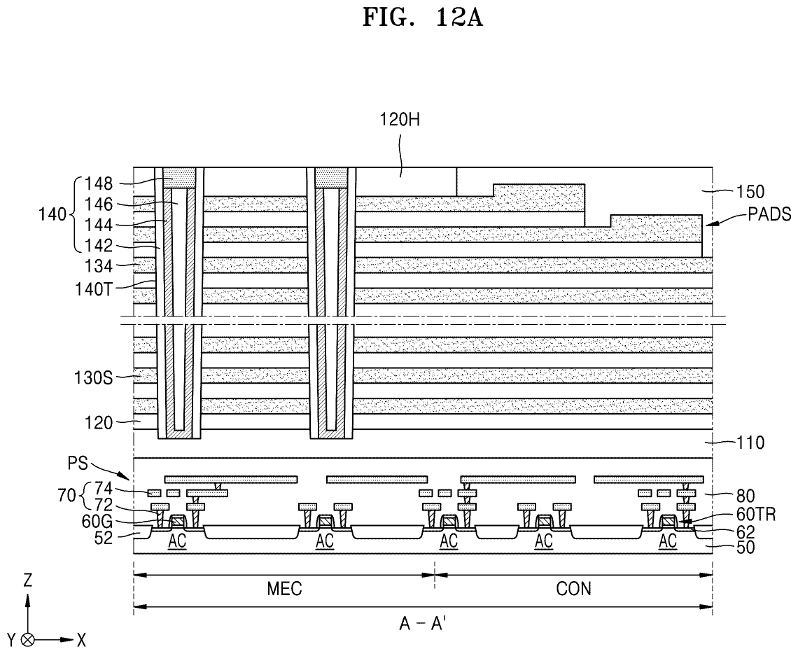

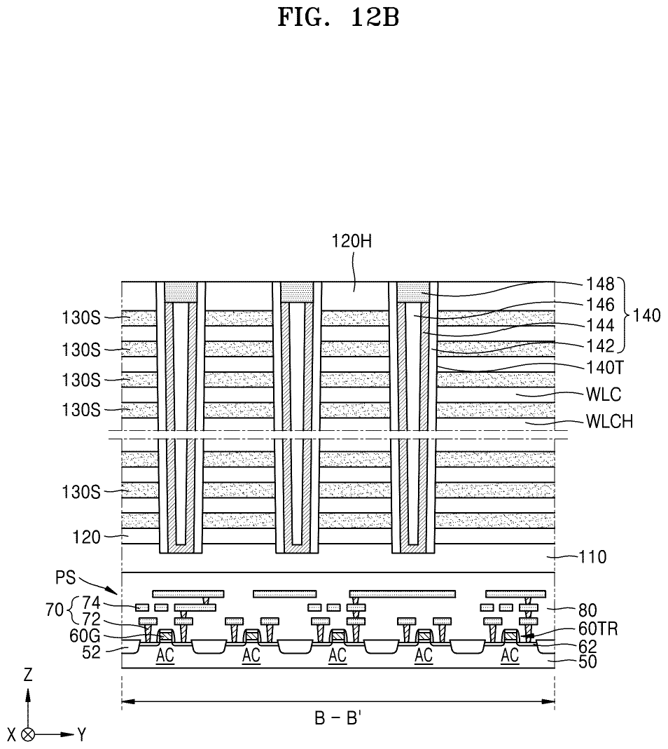

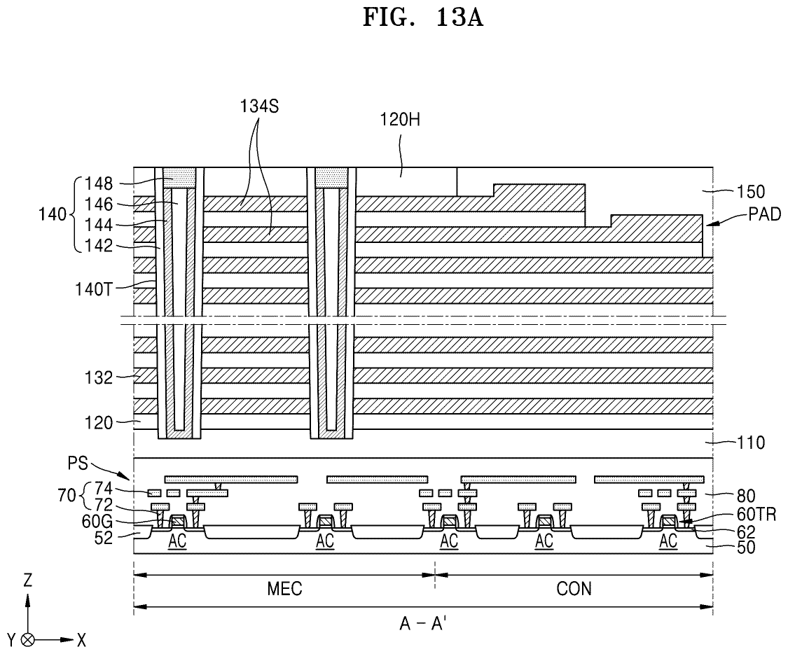

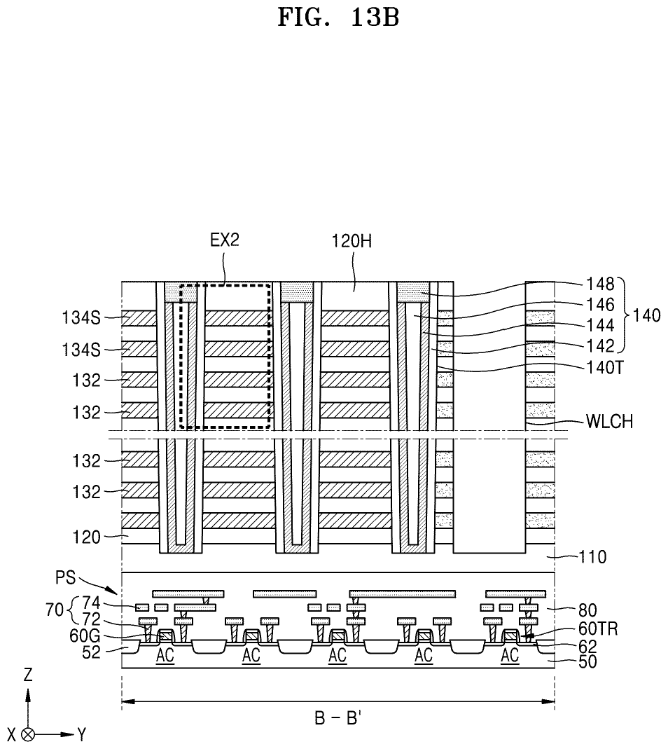

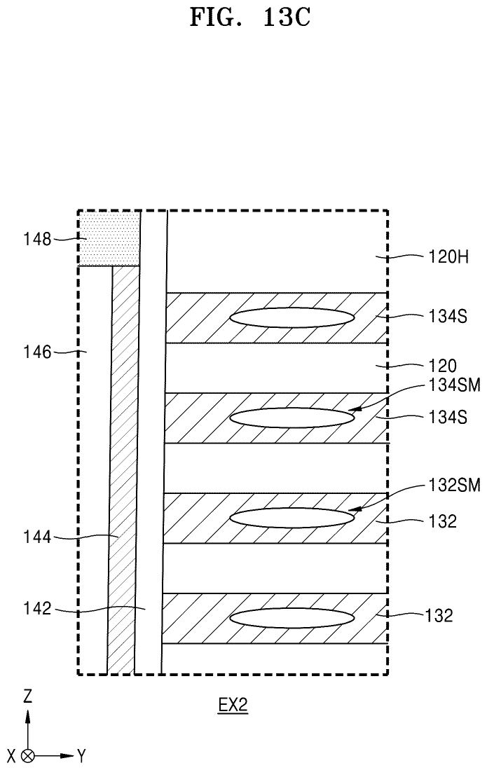

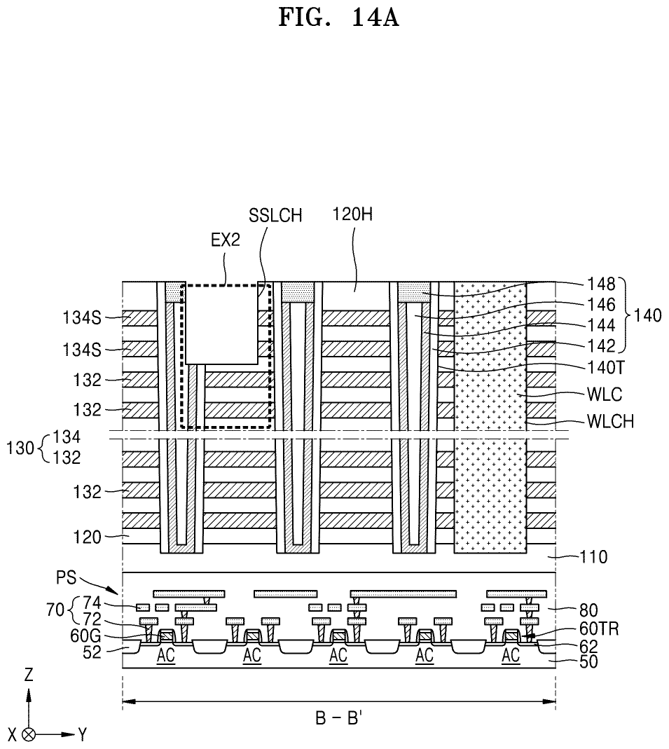

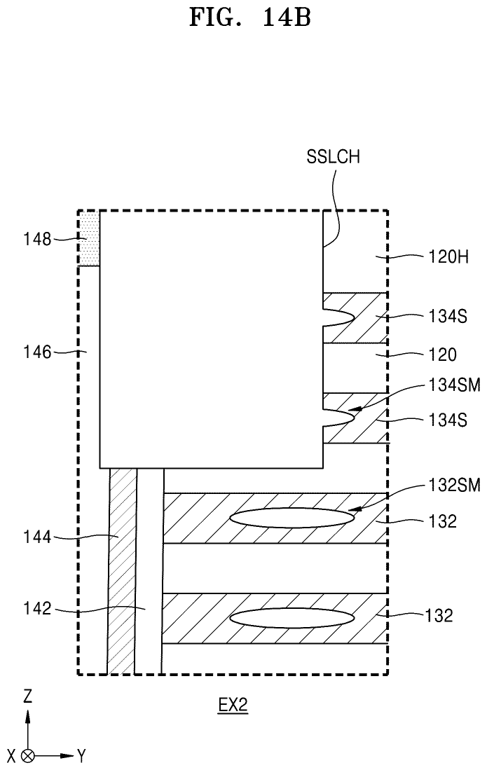

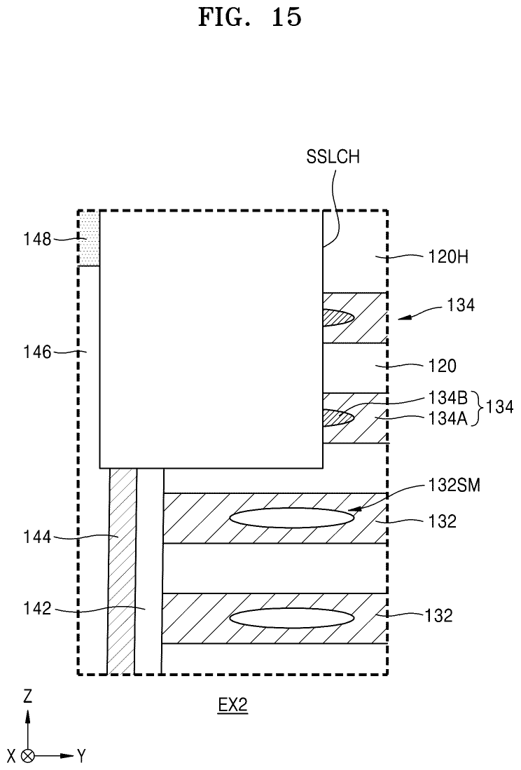

As seen in FIG. 8, the first gate line 132 may include a seam 132SM that is an empty space and in which conductive material is not present. The seam 132SM in the first gate line 132 may be formed in the plurality of first gate lines 132 in the process of replacing a plurality of sacrificial layers 130S (see FIG. 12A), which will be described below with reference to FIGS. 13A, 13B, and 13C, by a plurality of first gate lines 132 (see FIG. 13C) and a plurality of second gate lines 134S (see FIG. 13C). On the other hand, the second gate line 134 may not include a seam. That is, the second gate line 134 may be filled completely with a conductive material. This may be because, in a process described below with reference to FIGS. 14A, 14B, and 15, a seam 134SM (see FIG. 14B) formed in a plurality of second gate lines 134S (see FIG. 14B) is exposed by a second hole SSLCH and the exposed seam 134SM may be filled with a conductive material.

In some embodiments, the first gate line 132 may include a single conductive material. The conductive material may include, for example, a metal such as tungsten, nickel, cobalt, molybdenum, or tantalum, a metal silicide such as a tungsten silicide, a nickel silicide, a cobalt silicide, or a tantalum silicide, doped polysilicon, a titanium nitride, a tantalum nitride, a tungsten nitride, or any combination of two or more thereof.

The second gate line 134 may include a first conductive material layer 134A and a second conductive material layer 134B. The first conductive material layer 134A may be a portion of the second gate line 134 formed in a replacement process, which will be described below with reference to FIGS. 13A, 13B, and 13C, and the second conductive material layer 134B may be the other portion of the second gate line 134 formed in a process of filling the seam 134SM (see FIG. 14B) exposed by the second hole SSLCH with a conductive material, which will be described below with reference to FIGS. 14A, 14B, and 15. Thus, the interface where the first conductive material layer 134A and the second conductive material layer 134B contact each other may coincide with the surface of the seam 134SM (see FIG. 14B) exposed by the second hole SSLCH in a process described below with reference to FIGS. 14A, 14B, and 15. In some embodiments, the interface where the first conductive material layer 134A and the second conductive material layer 134B contact each other may have a shape rounded in a direction from the second conductive material layer 134B to the first conductive material layer 134A.

In some embodiments, the upper end portion of the second conductive material layer 134B may be located at a lower vertical level than the upper surface of the first conductive material layer 134A, and the lower end portion of the second conductive material layer 134B may be located at a higher vertical level than the lower surface of the first conductive material layer 134A. This may be because the second conductive material layer 134B may be formed by filling, with a conductive material, the seam 134SM (see FIG. 14B) formed in the second gate line 134S (see FIG. 14B) in a process described below with reference to FIGS. 14A, 14B, and 15.

In some embodiments, each of the first conductive material layer 134A and the second conductive material layer 134B may include a metal such as tungsten, nickel, cobalt, molybdenum, or tantalum, a metal silicide such as a tungsten silicide, a nickel silicide, a cobalt silicide, or a tantalum silicide, doped polysilicon, a titanium nitride, a tantalum nitride, a tungsten nitride, or any combination of two or more thereof.

In some embodiments, the first conductive material layer 134A may include the same material as the conductive material constituting the first gate line 132. For example, the first conductive material layer 134A and the first gate line 132 may include molybdenum.

In some embodiments, the first conductive material layer 134A and the second conductive material layer 134B may include the same conductive material. For example, each of the first conductive material layer 134A and the second conductive material layer 134B may include molybdenum.

In some embodiments, the first conductive material layer 134A and the second conductive material layer 134B may include different conductive materials. For example, the first conductive material layer 134A may include molybdenum, and the second conductive material layer 134B may include tungsten.

In some embodiments, the plurality of gate lines 130 may correspond to the ground selection line GSL (see FIG. 2), the word lines WL (WL1, WL2, . . . , WLn−1, WLn) (see FIG. 2), and at least one string selection line SSL (see FIG. 2) constituting the memory cell string MS (see FIG. 2). For example, the lowermost gate line 130 may function as the ground selection line GSL, the two uppermost gate lines 130 may function as the string selection line SSL, and the other gate lines 130 (e.g., those between the lowermost and two uppermost gate lines 130) may function as the word lines WL. Accordingly, the memory cell string MS in which the ground selection transistor GST (see FIG. 2), the string selection transistor SST (see FIG. 2), and the memory cell transistor (MC1, MC2, . . . , MCn−1, MCn) (see FIG. 2) therebetween are connected in series may be provided. In some embodiments, at least one of the gate lines 130 may function as a dummy word line; however, the inventive concepts of the present disclosure are not limited thereto.

In some embodiments, the second gate line 134 may include the string selection line SSL (see FIG. 2). For example, the two uppermost second gate lines 134 may both function as the string selection line SSL, and the plurality of first gate lines 132 may function as the word line WL and the ground selection line GSL. In some embodiments, one of the two uppermost second gate lines 134 may function as the string selection line SSL and the other one of the two uppermost second gate lines 134 may function as a word line WL, and the plurality of first gate lines 132 may function as word lines WL and as the ground selection line GSL.

A first hole WLCH may extend in the vertical direction (Z direction) through the plurality of insulating layers 120 and the plurality of gate lines 130, and a plurality of first separation patterns WLC may be arranged in the first hole WLCH. The plurality of first separation patterns WLC may extend in length or longitudinally in the first horizontal direction (X direction) in the memory cell area MEC and the connection area CON. A plurality of gate lines 130 arranged between two adjacent first separation patterns WLC among the plurality of first separation patterns WLC may constitute one memory cell block BLK. The width of each of the plurality of gate lines 130 constituting one memory cell block BLK in a second horizontal direction (Y direction) may be defined by the plurality of first separation patterns WLC.

Each of the plurality of first separation patterns WLC may include an insulating structure. In some embodiments, the insulating structure may include a silicon oxide, a silicon nitride, a silicon oxynitride, or a low dielectric material. For example, the insulating structure may include a silicon oxide layer, a silicon nitride layer, a SiON layer, a SiOCN layer, a SiCN layer, or any combination of two or more thereof. In some embodiments, at least a portion of the insulating structure may include an air gap.

A second hole SSLCH may extend in the vertical direction (Z direction) through at least a portion of a plurality of channel structures 140, at least a portion of a plurality of insulating layers 120, and a plurality of second gate lines 134 in one memory cell block BLK, and a second separation pattern SSLC may be arranged in the second hole SSLCH. The second separation pattern SSLC may extend in length or longitudinally in the first horizontal direction (X direction) in the memory cell area MEC. In another example, and in contrast to the illustration of FIG. 4, the second separation pattern SSLC may extend in length or longituindally in the first horizontal direction (X direction) in both the memory cell area MEC and the connection area CON. The second separation pattern SSLC may separate each of the plurality of second gate lines 134 in the second horizontal direction (Y direction). The second separation pattern SSLC may overlap at least a portion of the plurality of channel structures 140 in the vertical direction (Z direction). Accordingly, at least a portion of a channel structure 140 overlapping the second separation pattern SSLC in the vertical direction (Z direction) among the plurality of channel structures 140 may be removed by the second separation pattern SSLC. A first sidewall of the second separation pattern SSLC may contact the channel structure 140 penetrated by the second separation pattern SSLC in the first horizontal direction (X direction) and a second sidewall of the second separation pattern SSLC that is opposite the first sidewall may contact the plurality of second gate lines 134 penetrated by the second separation pattern SSLC.

FIGS. 4 to 8 illustrate that the second separation pattern SSLC penetrates two uppermost gate lines among the plurality of gate lines 130; however, the inventive concepts of the present disclosure are not limited thereto. For example, the second separation pattern SSLC may penetrate only one uppermost gate line among the plurality of gate lines 130 or may penetrate three or more uppermost gate lines among the plurality of gate lines 130. For example, when three uppermost gate lines among the plurality of gate lines 130 function as the string selection line SSL, in contrast to the examples in FIGS. 4 to 8 the second separation pattern SSLC may extend in the vertical direction (Z direction) to penetrate at least a portion of each of the three uppermost gate lines. In this case, the three uppermost gate lines penetrated by the second separation pattern SSLC may be referred to as the second gate lines 134, and the other gate lines other than the three uppermost gate lines may be referred to as the first gate line 132.

FIGS. 4 to 8 illustrate that the second separation pattern SSLC has a line shape extending in the first horizontal direction (X direction); however, the inventive concepts of the present disclosure are not limited thereto. For example, unlike the illustration in FIGS. 4 to 8, the second separation pattern SSLC may have a zigzag shape extending in the first horizontal direction (X direction).

The second separation pattern SSLC may be filled with an insulating layer. In some embodiments, the second separation pattern SSLC may include an insulating layer including an oxide layer, a nitride layer, or a combination of two or more thereof. In some embodiments, at least a portion of the second separation pattern SSLC may include an air gap.

FIGS. 4 to 8 illustrate that the upper surfaces of each of the first separation pattern WLC and the second separation pattern SSLC are located at the same vertical level as the upper surface of the uppermost insulating layer 120H; however, the inventive concepts of the present disclosure are not limited thereto. For example, in contrast to the illustrations of FIGS. 4 to 8 the upper surface of each of the first separation pattern WLC and the second separation pattern SSLC may be located at the same vertical level as the upper surface of a first upper insulating layer 160. In this case, the second separation pattern SSLC may extend to the upper surface of the first upper insulating layer 160 in the vertical direction (Z direction), and at least a portion of a bit line contact BLC arranged over the channel structure 140 penetrated by the second separation pattern SSLC may be penetrated by the second separation pattern SSLC.

The plurality of channel structures 140 may extend in the vertical direction (Z direction) from the upper surface of the common source plate 110 through the plurality of insulating layers 120 and the plurality of gate lines 130. The plurality of channel structures 140 may be arranged such that they are spaced apart from each other by a certain distance in the first horizontal direction (X direction) and the second horizontal direction (Y direction). For example, the plurality of channel structures 140 may be arranged to be spaced apart from each other by a certain distance in the second horizontal direction (Y direction) between a pair of second separation patterns SSLC spaced apart from each other in the second horizontal direction (Y direction). In this case, the number of channel structures 140 arranged in the second horizontal direction (Y direction) between a pair of second separation patterns SSLC spaced apart from each other in the second horizontal direction (Y direction) may be 1, 2, or 4 or more.

Each of the plurality of channel structures 140 may include a gate insulating layer 142, a channel layer 144, a buried insulating layer 146, and a conductive plug 148 arranged in a channel hole 140T.

The gate insulating layer 142 and the channel layer 144 may be sequentially arranged over the sidewall of the channel hole 140T. For example, the gate insulating layer 142 may be arranged on and may conform to the sidewall of the channel hole 140T, and the channel layer 144 may be arranged on and may conform to the sidewall and bottom surface of the channel hole 140T.

As illustrated in FIG. 7, the gate insulating layer 142 may include a tunneling dielectric layer 142A, a charge storage layer 142B, and a blocking dielectric layer 142C sequentially arranged over the outer wall of the channel layer 144. The relative thicknesses of the tunneling dielectric layer 142A, the charge storage layer 142B, and the blocking dielectric layer 142C constituting the gate insulating layer 142 are not limited to those illustrated in FIG. 7 and may be variously modified.

The tunneling dielectric layer 142A may include a silicon oxide, a hafnium oxide, an aluminum oxide, a zirconium oxide, a tantalum oxide, and/or the like. The charge storage layer 142B may be an area in which electrons having passed through the tunneling dielectric layer 142A from the channel layer 144 may be stored, and may include a silicon nitride, a boron nitride, a silicon boron nitride, or doped polysilicon. The blocking dielectric layer 142C may include a silicon oxide, a silicon nitride, or a metal oxide having a higher dielectric constant than a silicon oxide. The metal oxide may include a hafnium oxide, an aluminum oxide, a zirconium oxide, a tantalum oxide, or any combination of two or more thereof.

The channel layer 144 may have a cylindrical shape. The channel layer 144 may include doped polysilicon or undoped polysilicon. In some embodiments, the channel layer 144 may be arranged to contact the upper surface of the common source plate 110 at the bottom surface of the channel hole 140T. In examples, as illustrated in FIG. 4, the bottom surface of the channel layer 144 may be arranged at a lower vertical level than the upper surface of the common source plate 110; however, the inventive concepts of the present disclosure are not limited thereto.

The buried insulating layer 146 may be in (e.g., may fill) the internal space of the channel layer 144. The buried insulating layer 146 may include, for example, a silicon oxide, a silicon nitride, a silicon oxynitride, or any combination of two or more thereof. In some embodiments, the buried insulating layer 146 may be omitted. In this case, the channel layer 144 may have a pillar shape without an internal space.

The conductive plug 148 may contact the channel layer 144 on the upper side of the channel hole 140T and may block the entrance of the channel hole 140T. The conductive plug 148 may include, for example, a doped polysilicon layer.

In some embodiments, the plurality of gate electrodes 130 may extend to have a smaller length in the first horizontal direction X as it goes away from (e.g., as a distance increases from) the upper surface of the common source plate 110. That is, the plurality of gate lines 130 may have a stair shape. In this case, the edge portions of the gate line 130 arranged in a stair shape may be referred to as a gate pad portion PAD. However, the inventive concepts of the present disclosure are not limited thereto; for example, unlike the illustration in FIG. 5, each of the plurality of gate lines 130 may not have a gate pad portion PAD at the edge portions thereof and may have an flat upper surface in the first horizontal direction (X direction). In this case, in the connection area CON, the first contact plug 170 may extend more in the vertical direction (Z direction) than the illustration in FIG. 5 to contact the upper surface of one gate line 130 among the plurality of gate lines 130.

A cover insulating layer 150 may be arranged over the gate pad portion PAD, a first upper insulating layer 160 may be arranged over the uppermost insulating layer 120H and the cover insulating layer 150, and a second upper insulating layer 180 may be arranged over the first upper insulating layer 160. Each of the cover insulating layer 150, the first upper insulating layer 160, and the second upper insulating layer 180 may include an oxide layer, a nitride layer, or a combination thereof.

A first contact plug 170 penetrating the cover insulating layer 150 and the first upper insulating layer 160 in the vertical direction (Z direction) may be arranged in the connection area CON. The first contact plug 170 may be configured to be connected to one gate line 130 selected among the plurality of gate lines 130. The first contact plug 170 may contact the gate pad portion PAD of the selected one gate line 130 and may be connected to the selected one gate line 130 through the gate pad portion PAD. The first contact plug 170 may include, for example, tungsten, titanium, tantalum, copper, aluminum, a titanium nitride, a tantalum nitride, a tungsten nitride, or any combination of two or more thereof.

A second contact plug (not illustrated) penetrating the cover insulating layer 150, the first upper insulating layer 160, and the common source plate 110 in the vertical direction (Z direction) may be arranged in the connection area CON. The second contact plug may be configured to be connected to the peripheral circuit transistor 60TR through the peripheral circuit line layer 74. The second contact plug may include, for example, tungsten, titanium, tantalum, copper, aluminum, a titanium nitride, a tantalum nitride, a tungsten nitride, or any of two or more combination thereof.

In the memory cell area MEC, the bit line contact BLC may be connected to the channel structure 140 through the first upper insulating layer 160. In the memory cell area MEC, a bit line BL may be arranged over the first upper insulating layer 160 and connected to the bit line contact BLC.

In the connection area CON, a first line ML may be arranged over the first upper insulating layer 160 and may be connected to the first contact plug 170. Also, in the connection area CON, a second line (not illustrated) connected to the second contact plug may be arranged over the first upper insulating layer 160.

The semiconductor device 100 according to embodiments may include a first gate line 132 including a seam 132SM and a second gate line 134 including no seam. In this case, in a manufacturing process for the semiconductor device 100, a portion of the seam 134SM (see FIG. 14B) of the second gate line 134S (see FIG. 14B) may be removed by forming a second hole SSLCH, and the other portion of the seam 134SM (see FIG. 14B) of the second gate line 134S (see FIG. 14B), which remains without being removed, may include no seam by being filled with a conductive material through the second hole SSLCH. Because the second gate line 134 includes no seam, the conductive material constituting the second gate line 134 may be prevented from being oxidized or lost through the seam in a subsequent manufacturing process for the semiconductor device 100. Thus, the resistance of the second gate line 134 may be reduced and the malfunction of the second gate line 134 may be prevented, and thus, the electrical characteristics and operation reliability of the semiconductor device 100 may be improved.

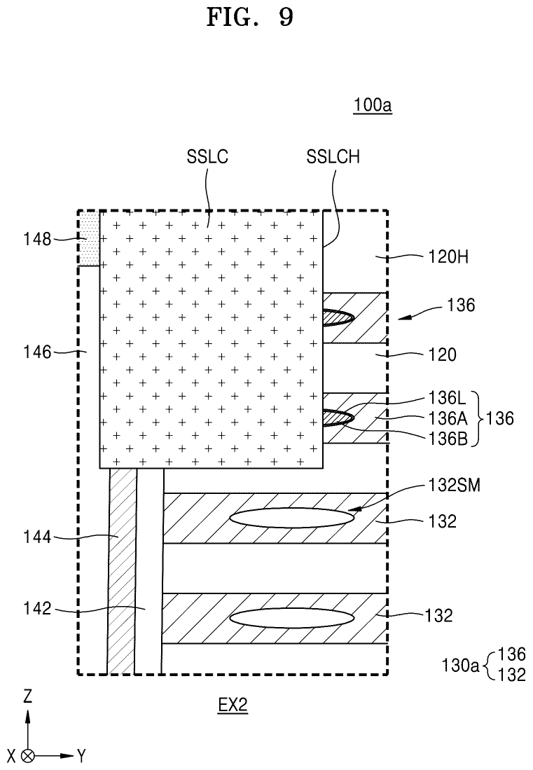

FIG. 9 is an enlarged cross-sectional view illustrating a semiconductor device 100a according to some embodiments. Particularly, FIG. 9 is an enlarged cross-sectional view of a region of the semiconductor device 100a corresponding to region EX2 of FIG. 6. Because the components of the semiconductor device 100a illustrated in FIG. 9 are similar to the components of the semiconductor device 100 described with reference to FIGS. 4 to 8, differences therebetween will be mainly described below in the interest of brevity.

Referring to FIG. 9, the semiconductor device 100a may have substantially the same configuration as the semiconductor device 100 illustrated in FIGS. 4 to 8, except that a second gate line 136 of the semiconductor device 100a may include an intermediate insulating layer 136L arranged between a first conductive material layer 136A and a second conductive material layer 136B.

The plurality of gate line may include a first gate line 132 and the second gate line 136. The second gate line 136 of the semiconductor device 100a may include a first conductive material layer 136A, a second conductive material layer 136B, and an intermediate insulating layer 136L. Each of the first conductive material layer 136A and the second conductive material layer 136B of the second gate line 136 may be substantially the same as or similar to the first conductive material layer 134A and the second conductive material layer 134B of the second gate line 134 illustrated in FIGS. 4 to 8, respectively.

The intermediate insulating layer 136L may be arranged between the first conductive material layer 136A and the second conductive material layer 136B. The intermediate insulating layer 136L may be an oxide layer formed along the surface of the seam 134SM (see FIG. 14B) by an etching process for forming the second hole SSLCH, which will be described below with reference to FIGS. 14A and 14B, or may be a natural oxide layer formed along the surface of the seam 134SM (see FIG. 14B) after the formation of the hole SSLCH and before the formation of the second conductive material layer 136B. Because the intermediate insulating layer 136L is formed along the surface of the seam 134SM (see FIG. 14B), the intermediate insulating layer 136L may have the same shape as the surface of the seam 134SM (see FIG. 14B). That is, the intermediate insulating layer 136L may have a rounded shape in a direction from the second conductive material layer 136B to the first conductive material layer 136A.

In some embodiments, the intermediate insulating layer 136L may be a metal oxide layer constituting the first conductive material layer 136A. For example, the first conductive material layer 136A may include molybdenum, and the intermediate insulating layer 136L may be a molybdenum oxide layer.

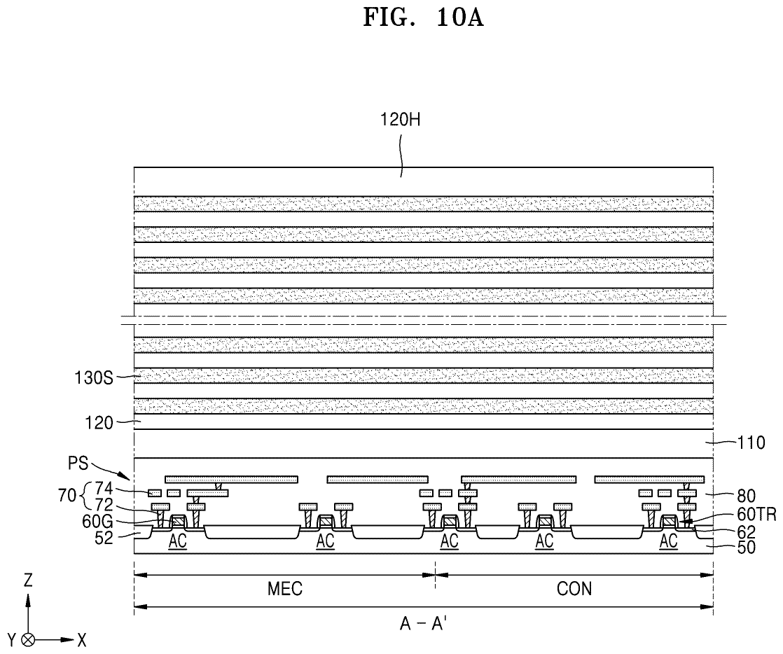

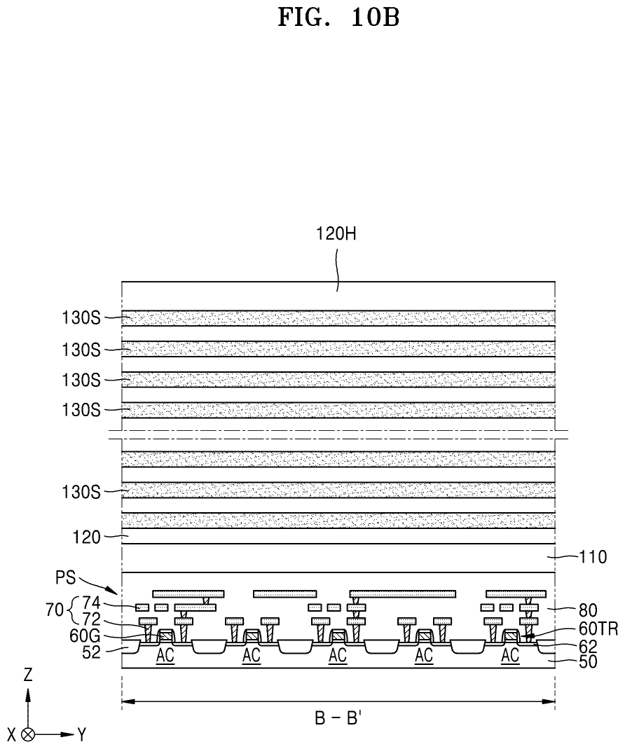

FIGS. 10A, 10B, 11, 12A, 12B, 13A, 13B, 13C, 14A, 14B, 15, 16A, 16B, 17A, and 17B are cross-sectional views for describing a semiconductor device (100) manufacturing method according to some embodiments. Particularly, FIGS. 10A, 11, 12A, 13A, and 17A are cross-sectional views taken along line A-A′ of FIG. 4, FIGS. 10B, 12B, 13B, 14A, 16A, and 17B are cross-sectional views taken along line B-B′ of FIG. 4, and FIGS. 13C, 14B, 15, and 16B are enlarged cross-sectional views of region EX2 of FIG. 6.

Referring to FIGS. 10A and 10B, a peripheral circuit structure PS including a peripheral circuit transistor 60TR, a peripheral circuit line structure 70, and an interlayer insulating layer 80 arranged over a substrate 50 may be provided. Next, a common source plate 110 may be formed over the peripheral circuit structure PS, and a plurality of insulating layers 120 and a plurality of sacrificial layers 130S may be alternately formed one by one over the common source plate 110. For example, the plurality of insulating layers 120 may include a silicon oxide layer, and the plurality of sacrificial layers 130S may include a silicon nitride.

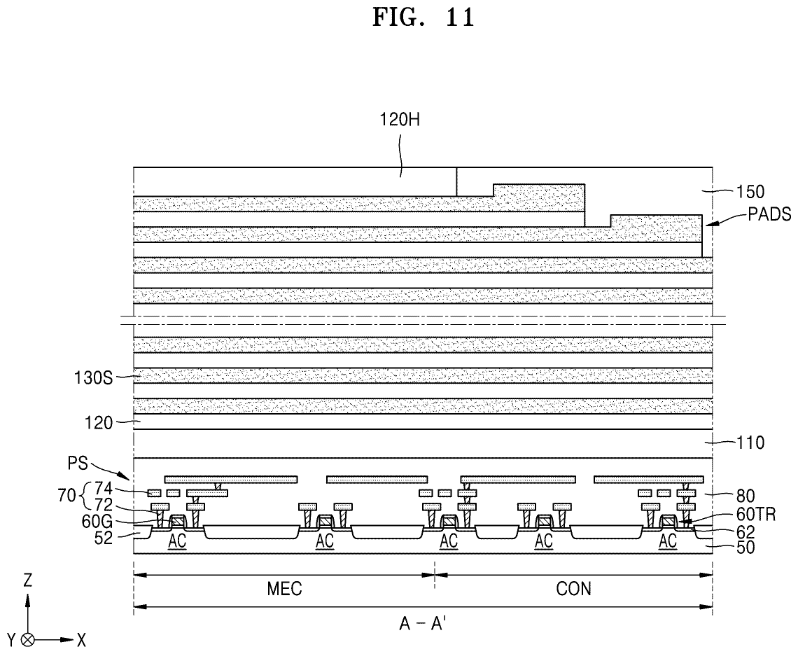

Referring to FIG. 11, in the connection area CON, by removing a portion of each of the plurality of insulating layers 120 and the plurality of sacrificial layers 130S by using a photolithography process, each of the plurality of insulating layers 120 and the plurality of sacrificial layers 130S may have a stair shape extending to have a smaller length in the first horizontal direction (X direction) as it goes away from (e.g., as a distance increases from) the upper surface of the common source plate 110. Next, a sacrificial pad portion PADS with an increased thickness may be formed at one end portion of each of the plurality of sacrificial layers 130S having a stair shape.

In some embodiments, in order to form the sacrificial pad portion PADS over one end portion of each of the plurality of sacrificial layers 130S, one end portion of each of the plurality of sacrificial layers 130S may be exposed by removing a portion of the plurality of insulating layers 120, and then, an additional layer including the same material as the component material of the plurality of sacrificial layers 130S may be deposited over the exposed one end portion of each of the plurality of sacrificial layers 130S, and the sacrificial pad portion PADS may be left by patterning the additional layer.

In some embodiments, a process of forming the sacrificial pad portion PADS may be omitted. In this case, after a replacement process described below with reference to FIGS. 12A, 12B, 13A, 13B, and 13C is performed, each of a plurality of first gate lines 132 (see FIG. 13A) and a plurality of second gate lines 134S (see FIG. 13A) formed by replacing the plurality of sacrificial layers 130S may have a flat upper surface without a gate pad portion PAD (see FIG. 13A) at the edge portion thereof.

Next, a cover insulating layer 150 covering the plurality of insulating layers 120 and the plurality of sacrificial layers 130S having a stair shape may be formed, and the uppermost insulating layer 120H may be exposed by planarizing the cover insulating layer 150.

Referring to FIGS. 12A and 12B, in the memory cell area MEC, a plurality of channel holes 140T may be formed. The plurality of channel holes 140T may penetrate the plurality of insulating layers 120 and the plurality of sacrificial layers 130S alternately stacked one by one, and the plurality of channel holes 140T may extend in length in the vertical direction (Z direction). A bottom portion of each of the channel holes 140T may extend into the common source plate 110. Next, a plurality of channel structures 140 including a gate insulating layer 142, a channel layer 144, a buried insulating layer 146, and a conductive plug 148 may be formed on the inner wall of each of the plurality of channel holes 140T.

Referring to FIGS. 13A, 13B, and 13C, a mask pattern (not illustrated) may be formed over the uppermost insulating layer 120H and the cover insulating layer 150, and a first hole WLCH may be formed. The first hole WLCH may penetrate the plurality of insulating layers 120 and the plurality of sacrificial layers 130S and may extend into the common source plate 110. The first hole WLCH may be formed by performing an etching process by using the mask pattern as an etch mask.

Next, in the memory cell area MEC and the connection area CON, the plurality of sacrificial layers 130S and the sacrificial pad portion PADS may be replaced by the plurality of first gate lines 132 and the plurality of second gate lines 134S through the internal space of each of the first holes WLCH. In each of the plurality of first gate lines 132 and the plurality of second gate lines 134S, a relatively thick one end portion obtained by replacing the sacrificial pad portion PADS may constitute a gate pad portion PAD.

Moreover, each of the plurality of first gate lines 132 and the plurality of second gate lines 134S formed through the replacement process may include seams 132SM and 134SM that are empty spaces.

Referring to FIGS. 14A and 14B, a plurality of first separation patterns WLC filling the first hole WLCH may be formed. Next, a mask pattern (not illustrated) may be formed over the uppermost insulating layer 120H in the memory cell area MEC, and a second hole SSLCH may be formed. The second hole SSLCH may penetrate at least a portion of each of the plurality of insulating layers 120 and the plurality of second gate lines 134S. The second hole SSLCH may be formed by performing an etching process by using the mask pattern as an etch mask.

The second hole SSLCH may overlap at least a portion of the plurality of channel structures 140 and each of the plurality of second gate lines 134S in the vertical direction (Z direction). Accordingly, at least a portion of a channel structure 140 overlapping the second separation pattern SSLC in the vertical direction (Z direction) among the plurality of channel structures 140 may be removed by the second hole SSLCH. Also, the plurality of second gate lines 134S may be separated from each other by the second hole SSLCH. Moreover, a portion of the seam 134SM of each of the plurality of second gate lines 134S overlapping the second hole SSLCH in the vertical direction (Z direction) may be removed by the second hole SSLCH, and the other portion of the seam 134SM of each of the plurality of second gate lines 134S, which remains without being removed by the second hole SSLCH, may be exposed by the second hole SSLCH and may communicate with the second hole SSLCH.

In some embodiments, after the plurality of channel structures 140 are formed as described with reference to FIGS. 12A and 12B, after the first upper insulating layer 160 is formed over the uppermost insulating layer 120H and the cover insulating layer 150, and after the process described with reference to FIGS. 13A and 13B is performed, the process described with reference to FIGS. 14A and 14B may be performed. In this case, each of the first hole WLCH and the second hole SSLCH may extend further in the vertical direction (Z direction) through the first upper insulating layer 160, and the first separation pattern WLC formed in the first hole WLCH and the second separation pattern SSLC formed in the second hole SSLCH may also extend further in the vertical direction (Z direction) through the first upper insulating layer 160.

Referring to FIG. 15, the remaining other portion of the seam 134SM (see FIG. 14B) of each of the plurality of second gate lines 134S (see FIG. 14B) may be filled with a conductive material through the second hole SSLCH. Accordingly, the plurality of second gate lines 134 may include the first conductive material layer 134A formed in the substitution process described with reference to FIGS. 13A, 13B, and 13C and the second conductive material layer 134A formed in the process described with reference to FIG. 15.

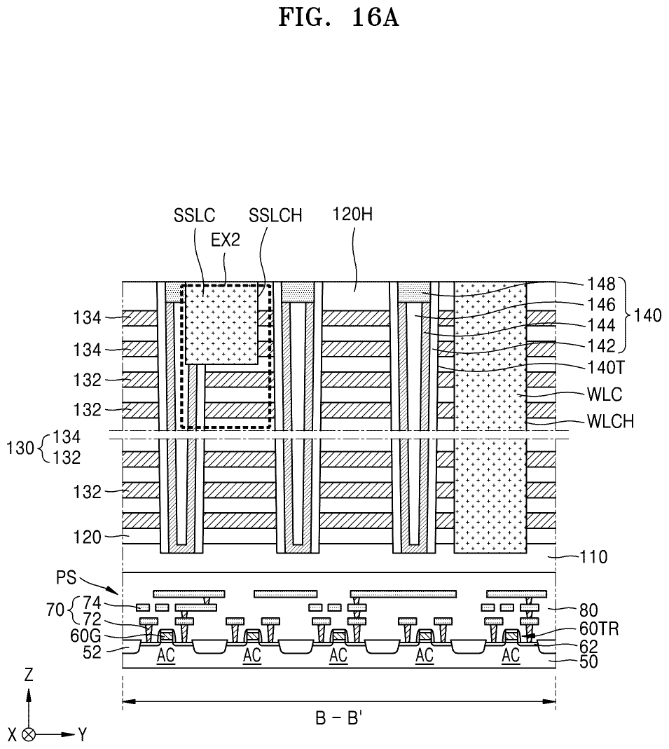

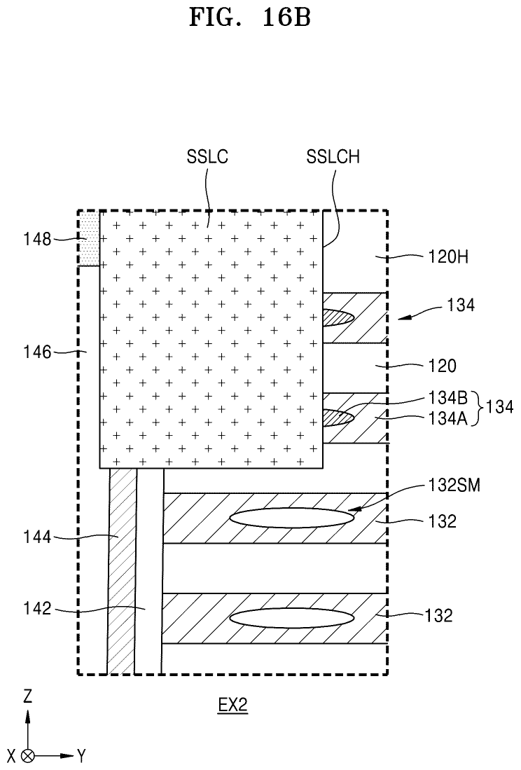

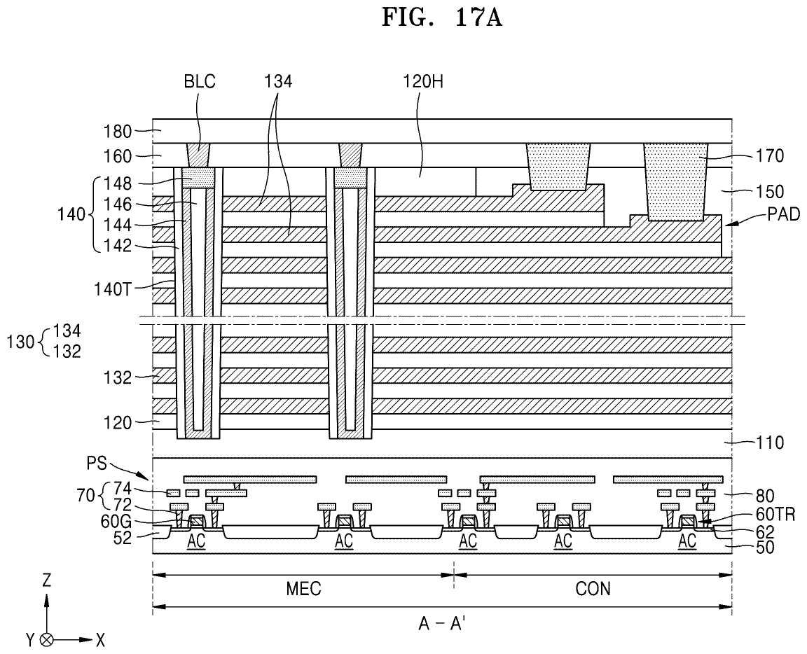

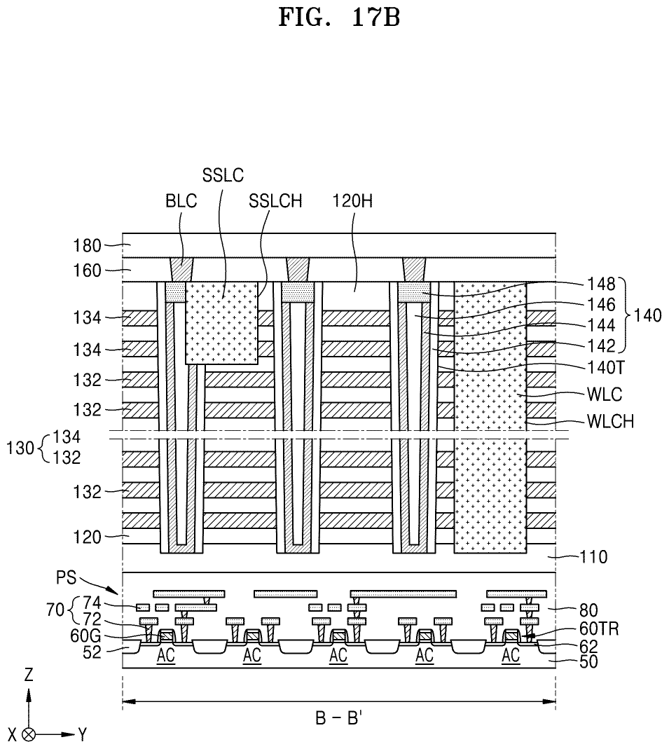

In some embodiments, an insulating layer (not illustrated) may be formed along the exposed surface of the remaining other portion of the seam 134SM (see FIG. 14B) of each of the plurality of second gate lines 134S (see FIG. 14B), and a conductive material may be formed over the insulating layer to fill the seam 134SM (see FIG. 14B) through the second line hole SSLCH. The insulating layer may be an oxide layer formed by the etching process for forming the second hole SSLCH described with reference to FIGS. 14A and 14B or may be a natural oxide layer formed before performing the process described with reference to FIG. 15 after forming the second hole SSLCH. Thereafter, by performing subsequent processes described below with reference to FIGS. 16A, 16B, 17A, and 17B, the semiconductor device 100a illustrated in FIG. 9 may be manufactured.

Referring to FIGS. 16A and 16B, a second separation pattern SSLC may be formed in the the second hole SSLCH and may fill a remaining part of the second hole SSLCH. The second separation pattern SSLC may contact the channel structure 140 and the second gate line 134 in the first horizontal direction (X direction) respectively on first and second sidewalls thereof.

Referring to FIGS. 17A and 17B, a first upper insulating layer 160 may be formed over the uppermost insulating layer 120H and the cover insulating layer 150. Next, a bit line contact BLC penetrating the first upper insulating layer 160 may be formed in the memory cell area MEC, and a first contact plug 170 penetrating the first upper insulating layer 160 and the cover insulating layer 150, and a second contact plug (not illustrated) penetrating the cover insulating layer 150, the first upper insulating layer 160, and the common source plate 110 may be formed in the connection area CON.

The bit line contact BLC may contact the conductive plug 148 of the channel structure 140 at the bottom surface thereof. The first contact plug 170 may contact the gate pad portion PAD at the bottom surface. The second contact plug may contact the peripheral circuit line layer 74 at the bottom surface thereof. Next, a second upper insulating layer 180 may be formed over the first upper insulating layer 160 in the memory cell area MEC and the connection area CON.

Next, in the resulting structure of FIGS. 17A and 17B, a bit line BL penetrating the second upper insulating layer 180 and connected to the bit line contact BLC may be formed in the memory cell area MEC, and a first line ML1 penetrating the second upper insulating layer 180 and connected to the first contact plug 170 and a second line (not illustrated) penetrating the second upper insulating layer 180 and connected to a second contact plug (not illustrated) may be formed in the connection area CON, thereby manufacturing the semiconductor device 100 illustrated in FIGS. 4 to 8.

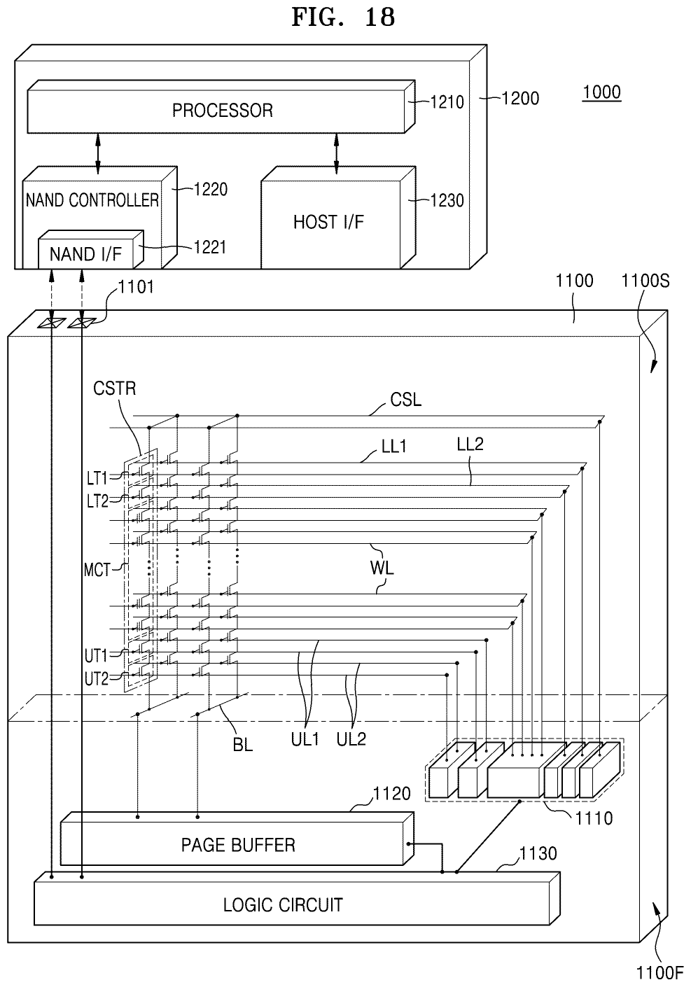

FIG. 18 is a diagram schematically illustrating an electronic system 1000 including a semiconductor device 1100 according to some embodiments.

Referring to FIG. 18, the electronic system 1000 according to some embodiments may include a semiconductor device 1100 and a controller 1200 electrically connected to the semiconductor device 1100. The electronic system 1000 may be a storage device including one or more semiconductor devices 1100 or may be an electronic device including a storage device. For example, the electronic system 1000 may be a solid state drive (SSD) device, a universal serial bus (USB) device, a computing system, a medical device, or a communication device including at least one semiconductor device 1100.

The semiconductor device 1100 may be a nonvolatile memory device. For example, the semiconductor device 1100 may be a NAND flash memory device including at least one of the structures described above with respect to the semiconductor devices 100 and 100a with reference to FIGS. 4 to 9. The semiconductor device 1100 may include a first structure 1100F and a second structure 1100S over the first structure 1100F. In some embodiments, the first structure 1100F may be arranged next the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT arranged between the upper transistors LT1 and LT2 and the lower transistors UT1 and UT2. The number of lower transistors LT1 and LT2 and the number of upper transistors UT1 and UT2 may be variously modified according to embodiments.

In some embodiments, the upper transistors UT1 and UT2 may include a string selection transistor, and the lower transistors LT1 and LT2 may include a ground selection transistor. The plurality of gate lower lines LL1 and LL2 may be respectively gate electrodes of the lower transistors LT1 and LT2. The word line WL may be a gate electrode of the memory cell transistor MCT, and the gate upper lines UL1 and UL2 may be gate electrodes of the upper transistors UT1 and UT2.

The common source line CSL, the plurality of gate lower lines LL1 and LL2, the plurality of word lines WL, and the plurality of gate upper lines UL1 and UL2 may be electrically connected to the decoder circuit 1110 through a plurality of first connection lines extending from the inside of the first structure 1100F to the second structure 1100S. The plurality of bit lines BL may be electrically connected to the page buffer 1120 through a plurality of second connection lines extending from the inside of the first structure 1100F to the second structure 1100S.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 through an input/output pad 1101 that is electrically connected to the logic circuit 1130. The input/output pad 1101 may be electrically connected to the logic circuit 1130 through an input/output connection line extending from the inside of the first structure 1100F to the second structure 1100S.

The controller 1200 may include a processor 1210, a NAND controller 1220, and a host interface 1230. According to some embodiments, the memory system 1000 may include a plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to certain firmware and may access the semiconductor device 1100 by controlling the NAND controller 1220. The NAND controller 1220 may include a NAND interface 1221 processing the communication with the semiconductor device 1100. A control command for controlling the semiconductor device 1100, data to be written into the plurality of memory cell transistors MCT of the semiconductor device 1100, data to be read from the plurality of memory cell transistors MCT of the semiconductor device 1100, and/or the like may be transmitted through the NAND interface 1221. The host interface 1230 may provide a communication function between the electronic system 1000 and an external host. When receiving a control command from the external host through the host interface 1230, the processor 1210 may control the semiconductor device 1100 in response to the control command.

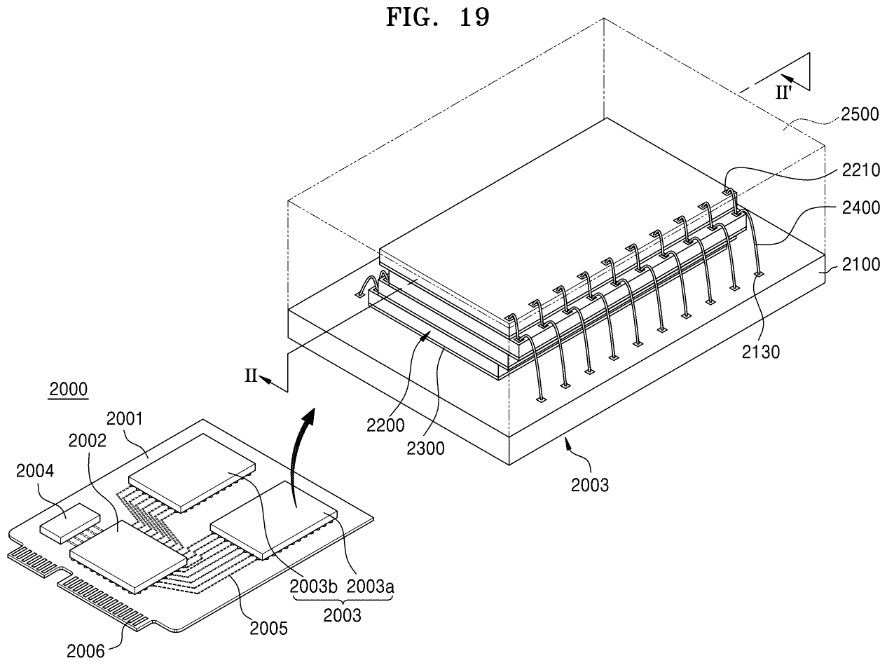

FIG. 19 is a perspective view schematically illustrating an electronic system 2000 including a semiconductor device according to some embodiments.

Referring to FIG. 19, the electronic system 2000 according to some embodiments may include a main board 2001 and a controller 2002, one or more semiconductor packages 2003, and a DRAM 2004 mounted on the main board 2001. The semiconductor package 2003 and the DRAM 2004 may be connected to the controller 2002 by a plurality of line patterns 2005 formed on the main board 2001.

The main board 2001 may include a connector 2006 including a plurality of pins coupled or couplable to an external host (not shown). The number and arrangement of the plurality of pins in the connector 2006 may vary according to the communication interface between the electronic system 2000 and the external host. In some embodiments, the electronic system 2000 may communicate with the external host according to any one of interfaces such as Universal Serial Bus (USB), Peripheral Component Interconnect Express (PCI-Express), Serial Advanced Technology Attachment (SATA), and Universal Flash Storage (UFS) M-Phy. In some embodiments, the electronic system 2000 may operate by the power supplied from the external host through the connector 2006. The electronic system 2000 may further include a power management integrated circuit (PMIC) that distributes the power supplied from the external host to the controller 2002 and the semiconductor package 2003.

The controller 2002 may write/read data into/from the semiconductor package 2003 and may improve the operating speed of the electronic system 2000.

The DRAM 2004 may be a buffer memory for reducing the speed difference between the external host and the semiconductor package 2003 that is a data storage space. The DRAM 2004 included in the electronic system 2000 may operate as a type of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b that are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 arranged on or over the package substrate 2100, an adhesive layer 2300 arranged on the lower surface of each of the plurality of semiconductor chips 2200, a connection structure 2400 that electrically connects the plurality of semiconductor chips 2200 to the package substrate 2100, and a molding layer 2500 that covers the plurality of semiconductor chips 2200 and the connection structure 2400 over the package substrate 2100.

The package substrate 2100 may be a printed circuit board including a plurality of package upper pads 2130. Each of the plurality of semiconductor chips 2200 may include an input/output pad 2210. The input/output pad 2210 may correspond to the input/output pad 1101 of FIG. 18. Each of the plurality of semiconductor chips 2200 may include at least one structure among the structures described above with respect to the semiconductor devices 100 and 100a with reference to FIGS. 4 to 9.

In some embodiments, the connection structure 2400 may be a bonding wire that electrically connects the input/output pad 2210 to the package upper pad 2130. Thus, in the first and second semiconductor packages 2003a and 2003b, the plurality of semiconductor chips 2200 may be electrically connected to each other by a bonding wire method and may be electrically connected to the package upper pad 2130 of the package substrate 2100. In some embodiments, in the first and second semiconductor packages 2003a and 2003b, the plurality of semiconductor chips 2200 may be electrically connected to each other by a connection structure including a through silicon via (TSV), instead of by the bonding wire type connection structure 2400.

In some embodiments, the controller 2002 and the plurality of semiconductor chips 2200 may be included in one package. In some embodiments, the controller 2002 and the plurality of semiconductor chips 2200 may be mounted on a separate interposer substrate that is different from the main board 2001, and the controller 2002 and the plurality of semiconductor chips 2200 may be connected to each other by a line formed on the interposer substrate.

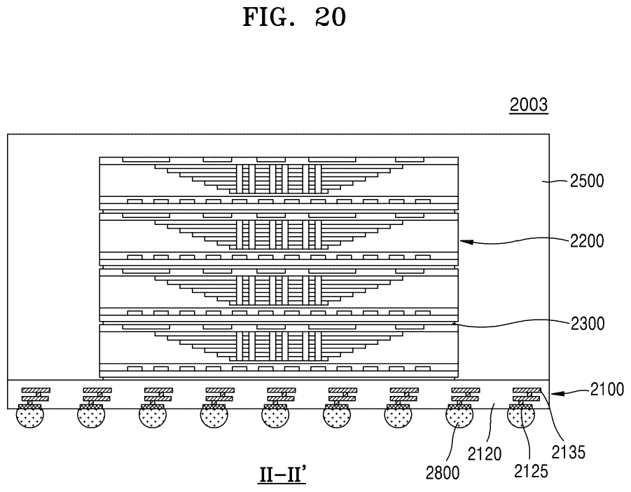

FIG. 20 is a cross-sectional view schematically illustrating semiconductor packages 2003 according to some embodiments. FIG. 20 illustrates a configuration along a cross-section taken along line II-II′ of FIG. 19 in greater detail.

Referring to FIG. 20, in the semiconductor package 2003, the package substrate 2100 may be a printed circuit board. The package substrate 2100 may include a package substrate body 2120, a plurality of package upper pads 2130 (see FIG. 19) arranged on the upper surface of the package substrate body 2120, a plurality of lower pads 2125 arranged on the lower surface of the package substrate body 2120 or exposed through the lower surface thereof, and a plurality of internal lines 2135 that electrically connect the plurality of package upper pads 2130 to the plurality of lower pads 2125 in the package substrate body 2120. The plurality of package upper pads 2130 may be electrically connected to the plurality of connection structures 2400. The plurality of lower pads 2125 may be connected through a plurality of conductive connection portions 2800 to the plurality of line patterns 2005 over the main board 2001 of the electronic system 2000 illustrated in FIG. 19.

In some embodiments, each of the plurality of semiconductor chips 2200 may include at least one structure among the structures described above with respect to the semiconductor devices 100 and 100a with reference to FIGS. 4 to 9.

While the inventive concepts of the present disclosure have been particularly shown and described with reference to some examples of embodiments thereof, it will be understood that various changes in form and details may be made therein without departing from the scope of the following claims.

What is claimed is:

1. A semiconductor device comprising:
a plurality of gate lines comprising a first gate line arranged over a substrate and a second gate line arranged over the first gate line;
a plurality of insulating layers respectively arranged between the plurality of gate lines;
a plurality of channel structures that penetrate the plurality of gate lines in a vertical direction that is perpendicular to an upper surface of the substrate; and
a separation pattern that overlaps at least a portion of the plurality of channel structures in the vertical direction,
wherein the separation pattern penetrates at least a portion of the second gate line and at least a portion of a first channel structure of the plurality of channel structures, the first channel structure overlapping the separation pattern in the vertical direction, and
wherein the second gate line is filled completely with a conductive material.

2. The semiconductor device of claim 1, wherein the first gate line includes a seam in which conductive material is not present.

3. The semiconductor device of claim 1, wherein the separation pattern includes first and second sidewalls both extending longitudinally in a horizontal direction, and
wherein the first sidewall of the separation pattern contacts the first channel structure and the second sidewall contacts the second gate line.

4. The semiconductor device of claim 1, wherein the first gate line comprises a single conductive material.

5. The semiconductor device of claim 1, wherein the second gate line comprises a first conductive material layer and a second conductive material layer that is surrounded by the first conductive material layer.

6. The semiconductor device of claim 5, wherein the first conductive material layer and the second conductive material layer comprise a same conductive material.

7. The semiconductor device of claim 5, wherein an upper end portion of the second conductive material layer is located at a lower vertical level than an upper surface of the first conductive material layer, and a lower end portion of the second conductive material layer is located at a higher vertical level than a lower surface of the first conductive material layer.

8. The semiconductor device of claim 5, further comprising an intermediate insulating layer that is arranged between the first conductive material layer and the second conductive material layer.

9. The semiconductor device of claim 8, wherein the intermediate insulating layer comprises an oxide layer of a conductive material of the first conductive material layer.

10. The semiconductor device of claim 1, wherein the second gate line comprises a string selection line.

11. A semiconductor device comprising:
a peripheral circuit structure comprising a substrate, a peripheral circuit arranged over the substrate, and a peripheral circuit line structure connected to the peripheral circuit;
a common source plate arranged over the peripheral circuit structure;
a plurality of gate lines comprising a first gate line arranged over the common source plate and a second gate line arranged over the first gate line;
a plurality of insulating layers respectively arranged between the plurality of gate lines;
a plurality of channel structures that penetrate the plurality of gate lines in a vertical direction perpendicular to an upper surface of the substrate;
a first separation pattern that is horizontally spaced apart from the plurality of channel structures and that penetrates the plurality of gate lines in the vertical direction; and
a second separation pattern that is horizontally spaced apart from the first separation pattern and that overlaps at least a portion of the plurality of channel structures in the vertical direction,
wherein the second separation pattern penetrates at least a portion of the second gate line and at least a portion of a first channel structure of the plurality of channel structures, the first channel structure overlapping the second separation pattern in the vertical direction, and
wherein the second gate line is filled completely with a conductive material.

12. The semiconductor device of claim 11, wherein the first gate line comprises a single conductive material and includes a seam in which conductive material is not present.

13. The semiconductor device of claim 11, wherein the second separation pattern includes first and second sidewalls that extend longitudinally in a horizontal direction, and wherein the first sidewall of the second separation pattern contacts the first channel structure and the second sidewall contacts the second gate line.

14. The semiconductor device of claim 11, wherein the second gate line comprises a first conductive material layer and a second conductive material layer that is surrounded by the first conductive material layer.

15. The semiconductor device of claim 14, wherein an upper end portion of the second conductive material layer is located at a lower vertical level than an upper surface of the first conductive material layer, and a lower end portion of the second conductive material layer is located at a higher vertical level than a lower surface of the first conductive material layer.

16. The semiconductor device of claim 14, wherein the first conductive material layer and the first gate line comprise a same conductive material.

17. The semiconductor device of claim 14, further comprising an intermediate insulating layer that is arranged between the first conductive material layer and the second conductive material layer, wherein the intermediate insulating layer comprises an oxide layer of a conductive material of the first conductive material layer.

18. The semiconductor device of claim 11, wherein the second gate line comprises a string selection line.

19. An electronic system comprising:
a main board;
a semiconductor device over the main board; and
a controller that is electrically connected to the semiconductor device,
wherein the semiconductor device comprises:
a plurality of gate lines comprising a first gate line that is arranged over a substrate and a second gate line that is arranged over the first gate line;
a plurality of insulating layers respectively arranged between the plurality of gate lines;
a plurality of channel structures that penetrate the plurality of gate lines in a vertical direction that is perpendicular to an upper surface of the substrate; and
a separation pattern that overlaps at least a portion of the plurality of channel structures in the vertical direction,
wherein the separation pattern penetrates at least a portion of the second gate line and at least a portion of a first channel structure of the plurality of channel structures, the first channel structure overlapping the separation pattern in the vertical direction, and
wherein the second gate line is filled completely with a conductive material.

20. The electronic system of claim 19, wherein the first gate line comprises a single conductive material and includes a seam in which conductive material is not present.
